(19) United States
(12) Patent Application Publication
(10) Pub. No.: US 2022/0254909 A1
(43) Pub. Date: Aug. 11, 2022

(54) Tunnel Field-Effect Transistor and Method for Manufacturing the Same

(71) Applicant: Nippon Telegraph and Telephone Corporation, Tokyo (JP)

(72) Inventors: Manabu Mitsuhara, Tokyo (JP); Hiroki Sugiyama, Tokyo (JP)

(21) Appl. No.: 17/621,143

(22) PCT Filed: Jun. 27, 2019
(86) PCT No.: PCT/JP2019/025543

§ 371 Date: Dec. 20, 2021

(51) Int. Cl. H01L 29/775; H01L 29/205; H01L 29/66; H01L 29/207

(52) U.S. Cl. CPC H01L 29/775; H01L 29/207; H01L 29/66439; H01L 29/205

(57) ABSTRACT

A channel layer has a quantum well structure including InGaAs or InGaAsSb, and includes a first barrier layer, a well layer, and a second barrier layer. A first intermediate layer is provided between the first barrier layer and the well layer, and a second intermediate layer is provided between the second barrier layer and the well layer. The first and second intermediate layers include InGaAs or InGaAsSb having an In composition ratio greater than that of the first and second barrier layers and smaller than that of the well layer.

This patent application is a national phase filing under section 371 of PCT application no. PCT/JP2019/025543, filed on June 27, 2019, which application is incorporated herein by reference in its entirety.

### TECHNICAL FIELD

The present invention relates to a tunnel field effect transistor and a method for manufacturing the same.

### BACKGROUND

With the recent advancement of the Internet of Things (IoT) and cloud computing, there is concern that the ratio of information-related fields to total power consumption will increase rapidly. Many metal oxide semiconductor field effect transistors (MOSFETs) are used in information-related devices such as network devices, servers, personal computers, and mobile terminals. Therefore, there is an urgent need to reduce the power consumption of MOSFETs in order to suppress the increase in power consumption of information-related equipment.

The field effect transistor switches between the on state and the off state by changing the drain current according to the gate voltage. In order to reduce the drive voltage, it is important that the drain current rises sharply with respect to the gate voltage. As this performance index, the S value (unit: mV/decade) is used, which is the gate voltage required to increase the drain current by an order of magnitude at the rising edge of the I-V curve. The smaller the S value, the lower the drive voltage that can be expected.

However, in a MOSFET, it is difficult in principle to reduce the S value at room temperature to 0.6 mV/decade or less. On the other hand, in a tunnel field effect transistor (TFET) whose operating principle is different from that of A MOSFET, an S value of 0.6 mV/decade or less can be obtained. Therefore, research and development of tunnel field effect transistors are currently being actively promoted.

As a performance index of the tunnel field effect transistor, in addition to the S value above, the ratio of current in the on and off states is important. Specifically, when the drain current in the on state is referred to as the on-current herein and the drain current in the off state is referred to as the off-current herein, the higher the ratio of the on-current to the off-current (I_{ON}/I_{OFF}), the better the device characteristics. In order to increase the on-current, it is necessary to increase the tunnel current, and an effective means for this is to use a material with a small bandgap in the tunnel junction region.

However, in a tunnel field effect transistor using only a material having a small bandgap, it is difficult to increase the above current ratio (I_{ON}/I_{OFF}) because the off-current is also high. In order to solve this problem, it is necessary to use a material having a small bandgap only in the layer through which the tunnel current flows, and to use a material having a large bandgap in the other layers.

The bandgap (˜1.35 eV) of InP is larger than that of silicon (˜1.12 eV), and high quality substrates are commercially available. The structure obtained by growing InGaAs lattice-matched to InP on the InP substrate is a useful structure for the tunnel field effect transistor in order to satisfy the above-mentioned requirements, because the structure can have a bandgap smaller than silicon near the layer where the tunnel current flows and larger than silicon in other areas. In fact, a tunnel field effect transistor including this structure has been reported to have good device characteristics (see, for example, Non Patent Literature 1).

In order to further increase the on-current of the tunnel field effect transistor, it is effective to make the bandgap of the layer through which the tunnel current flows smaller than that of InGaAs lattice-matched to InP. As a method for this, a quantum well structure in which an InGaAs well layer having a large In composition ratio is sandwiched between InGaAs barrier layers on an InP substrate (In composition ratio: up to 0.53) and a structure using InGaAsSb which can have a smaller bandgap than InGaAs have been studied (see, for example, Non Patent Literature 2).

### CITATION LIST

### Non Patent Literature

Non-Patent Literature 1: M. Noguchi et al., “High Ion/I_{off} and Low Subthreshold Slope Planar-type InGaAs Tunnel Field Effect Transistors with Zn-diffused Source Junctions”, Journal of Applied Physics, vol. 118, no. 4, 045712, 2015.

Non Patent Literature 2: D.-H. Ahn et al., “Design and Properties of Planar-type Tunnel FETs Using In_{0.53}Ga_{0.47}As/InₓGa₁₋ₓAs/In_{0.53}Ga_{0.47}As Quantum Well”, Journal of Applied Physics, vol. 122, no. 13, 135704, 2017.

### SUMMARY

### Technical Problem

In a tunnel field effect transistor including a quantum well structure on an InP substrate, reduction of the bandgap of the well layer is useful to increase the on-current. In this case, since the film thickness of the general well layer is as thin as 10 nm or less, the off-current seemingly does not increase remarkably even if the bandgap of the well layer becomes slightly smaller. However, in a tunnel field effect transistor including an InGaAs quantum well on an actual InP, it is known that the off-current increases sharply when the bandgap of the well layer becomes small (see, for example, Non Patent Literature 2). This cause is considered to be related to the layer structure of the tunnel field effect transistor and the method for manufacturing the same described below.

Hereinafter, the tunnel field effect transistor will be described with reference to FIG. 11. The tunnel field effect transistor includes an InP layer 302 formed on a substrate 301, a barrier layer 303 comprising InGaAs formed on the InP layer 302, a well layer 304 comprising InGaAs, and a barrier layer 305 comprising InGaAs. The substrate 301 comprises InP which is semi-insulating by doping with Fe. In this tunnel field effect transistor, the barrier layer 303, the well layer 304, and the barrier layer 305 form a channel layer having a quantum well structure.

A source region 306 and a drain region 307 are formed in the barrier layer 303, the well layer 304, and the barrier layer 305 at predetermined intervals. The source region 306 is of p-type and the drain region 307 is of n-type. The source region 306 is formed by selective p-type doping into this region, for which Zn diffusion is used (see, for example, Non Patent Literatures 1 and 2). Further, the drain region 307 is formed by n-type doping for this region using a method applying ion implantation or diffusion. Further, a source electrode 316 is formed in electrical connection with the source region 306, and a drain electrode 317 is formed in electrical connection with the drain region 307.

Further, an intentionally undoped region is provided between the source region 306 and the drain region 307, and a gate electrode 309 is formed on the region via a gate insulating film 308. The source region 306, the intentionally undoped region (channel region), and the drain region 307 are arranged in this order in the gate length direction.

In this tunnel field effect transistor, the interface between the above-described intentionally undoped region and the source region 306 is a tunnel junction interface 310. In the tunnel field effect transistor, on and off are switched by controlling the probability that electrons tunnel from the valence band to the conduction band at the tunnel junction interface 310 by the gate voltage. Therefore, the on-current and off-current of the tunnel field effect transistor largely depend on the band arrangement near the tunnel junction interface.

FIG. 12 illustrates an enlarged view of the vicinity of the tunnel junction interface 310 in the tunnel field effect transistor described above. In FIG. 12, the right side of the tunnel junction interface 310 is an undoped region, and the left side is the p-type doped source region 306. FIG. 13 schematically illustrates a band arrangement along the line indicated by Z₁ on the non-doped side of the tunnel junction interface 310 in FIG. 12. The quantum well structure is a structure in which the well layer 304 and the barrier layers 303 and 305 having different bandgaps are laminated, and band discontinuity occurs at the interfaces between the well layer 304 and the barrier layers 303 and 305.

In the undoped state, the energies of the well layer 304 and the barrier layers 303 and 305 at the bottom of the conduction band and the top of the valence band are not related to the distance from the crystal surface (Z axis in FIG. 12), and take constant values in the well layer 304 and the barrier layers 303 and 305, respectively. FIG. 14 schematically illustrates the band arrangement along the line shown by Z₂ on the p-type doped side (source region 306) of the tunnel junction interface 310 of FIG. 12. In this case, since the band is curved by p-type doping, the energies of the well layer 304 and the barrier layers 303 and 305 at the bottom of the conduction band and the top of the valence band change depending on the distance from the crystal surface.

Due to the curvature of this band, spikes and depressions are generated in the valence band at the interfaces between the well layer 304 and the barrier layers 303 and 305. Of these, the one that has a large effect on the tunnel current is the spikes in the well layer 304 through which the current actually flows. These spikes basically enlarge as the difference in bandgap between the well layer 304 and the barrier layers 303 and 305 increases. The effect of spikes in the valence band of the well layer 304 on the operation of the tunnel field effect transistor will be described below.

In the tunnel field effect transistor described above, a current flows by electrons tunneling from the p-type doped left valence band (source region 306) to the undoped right conduction band in the well layer 304. When there is band curvature due to the p-type doping described above, the tunneling of electrons in the well layer 304 differs in dependence on the gate voltage near the central portion of the well layer 304 and its interfaces with the barrier layers 303 and 305.

FIGS. 15 and 16 schematically illustrate how electron tunneling occurs in the well layer 304 when a gate voltage is applied near the central portion (X-1 in FIG. 12) and near the interface with the barrier layer 305 (X-2 in FIG. 12). In the tunnel field effect transistor, the application of the gate voltage lowers the position of the conduction band in the undoped layer, so that electrons are tunneled from the valence band in the p-type doped region to the conduction band in the undoped region.

At this time, the gate voltage required for electron tunneling to occur decreases as the position of the valence band in the p-type doped region increases energetically. As illustrated in FIG. 14, when the quantum well structure is p-type doped, in the valence band of the well layer 304, the energy rises near the interface with the barrier layers 303 and 305, so that electron tunneling occurs even at a gate voltage smaller than that near the center of the well layer 304. For this reason, electron tunneling in the well layer 304 preferentially occurs near the interfaces with the barrier layers 303 and 305, which is a problem in reducing the off-current of the field effect transistor.

The above-described problem will be described below. The interfaces between the well layer and the barrier layers described above are heterojunction interfaces in which materials having different group III and group V compositions are bonded. At the heterojunction interfaces, the bonding state between atoms on the crystal growth surface is different from that inside the well layer and the barrier layers, so that crystal defects are likely to occur. Further, in order to form a heterojunction interface, it is necessary to change the amount of raw material supplied at this interface, so that the growth interruption in which the group III raw material is not supplied is installed and the substrate temperature is adjusted. Therefore, the flatness of the crystal surface tends to deteriorate, and crystal defects are likely to occur.

If there is a crystal defect at the heterojunction interface, leakage current tends to flow through the tunnel junction, which is a pn junction, and as a result, the off-current increases. As described above, the spikes in the valence band in the well layer basically increase as the difference between the bandgaps of the well layer and the barrier layers increases. Therefore, if the bandgap of the well layer is reduced in order to increase the on-current, the spikes in the valence band of the well layer also increase, and as a result, the off-current increases. As a result, it was difficult to increase both the on-current and the ratio of the on-current to the off-current (see, for example, Non Patent Literature 2).

Embodiments of the present invention can solve the above problems, and an object of embodiments of the present invention is to reduce the off-current of a tunnel field effect transistor including a quantum well structure channel layer as a quantum well structure.

### Means for Solving the Problem

The tunnel field effect transistor according to embodiments of the present invention includes: a channel layer having a quantum well structure and comprising InGaAs or InGaAsSb; an intermediate layer formed between a well layer and a barrier layer, and comprising InGaAs or InGaAsSb and having an In composition ratio greater than an In composition ratio of the barrier layer and smaller than an In composition ratio of the well layer, the well layer and the barrier layer constituting the channel layer; a p-type source region formed in the channel layer; an n-type drain region formed in the channel layer at a predetermined interval from the source region; a source electrode formed in connection with the source region; a drain electrode formed in connection with the drain region; and a gate electrode formed above a channel region between the source region and the drain region.

In one configuration example of the tunnel field effect transistor, the In composition ratio of the intermediate layer is higher toward the well layer side.

In one configuration example of the tunnel field effect transistor, the In composition ratio of the intermediate layer continuously decreases from the well layer to the barrier layer.

A method for manufacturing a field effect transistor according to embodiments of the present invention is a method for manufacturing the tunnel field effect transistor, and the source region is made p-type by Zn diffusion.

### Effects of Embodiments of the Invention

As described above, according to embodiments of the present invention, an intermediate layer comprising InGaAs or InGaAsSb having an In composition ratio greater than that of the barrier layer and smaller than that of the well layer is provided between the well layer and the barrier layer constituting the channel layer, which can reduce the off-current of the tunnel field effect transistor including a quantum well structure channel layer as a quantum well structure.

### BRIEF DESCRIPTION OF THE DRAWINGS

FIG. 1 is a cross-sectional view illustrating a configuration of a tunnel field effect transistor according to an embodiment of the present invention.

FIG. 2 is a cross-sectional view illustrating a partial configuration of the tunnel field effect transistor according to an embodiment of the present invention.

FIG. 3 is a band diagram illustrating a band arrangement in the thickness direction in the source region of the channel layer when the intermediate layers of the tunnel field effect transistor according to an embodiment are composition gradient layers.

FIG. 4 is a cross-sectional view illustrating a partial configuration of another tunnel field effect transistor according to an embodiment of the present invention.

FIG. 5 is a band diagram illustrating a band state in the source region of the tunnel field effect transistor described with reference to FIG. 4.

FIG. 6 is a characteristic diagram illustrating changes in the In composition ratio and the Ga composition ratio of InGaAs from the surface side in the laminated structure of a tunnel field effect transistor according to an embodiment.

FIG. 7 is a characteristic diagram comparing the results of an experimental X-ray diffraction pattern and a simulated X-ray diffraction pattern of the laminated structure of tunnel field effect transistors according to an embodiment.

FIG. 8A is a photograph illustrating the result of examining the distribution state of In near the crystal surface of the laminated structure of a tunnel field effect transistor according to an embodiment using EDS.

FIG. 8B is a photograph illustrating the result of examining the distribution state of Ga near the crystal surface of the laminated structure of a tunnel field effect transistor according to an embodiment using EDS.

FIG. 9 is a characteristic diagram illustrating the ratios of In, Ga, and As in the laminated structure obtained by analyzing the spectra of EDS illustrated in FIGS. 8A and 8B.

FIG. 10 is a characteristic diagram illustrating a photoluminescence spectrum of a laminated structure of a tunnel field effect transistor according to an embodiment at room temperature.

FIG. 11 is a cross-sectional view illustrating the configuration of a tunnel field effect transistor.

FIG. 12 is a cross-sectional view illustrating a partial configuration of the tunnel field effect transistor of FIG. 11.

FIG. 13 is a band diagram illustrating a band arrangement along the line indicated by Z₁ on the undoped side of the tunnel junction interface in FIG. 12.

FIG. 14 is a band diagram illustrating a band arrangement along the line indicated by Z₂ on the p-type doped side (source region) of the tunnel junction interface in FIG. 12.

FIG. 15 is a band diagram illustrating how tunneling of electrons occurs when a gate voltage is applied near a central portion of the well layer (X-1 in FIG. 12).

FIG. 16 is a band diagram illustrating how tunneling of electrons occurs when a gate voltage is applied near the interface of the well layer with the barrier layer (X-2 in FIG. 12).

### DETAILED DESCRIPTION OF ILLUSTRATIVE EMBODIMENTS

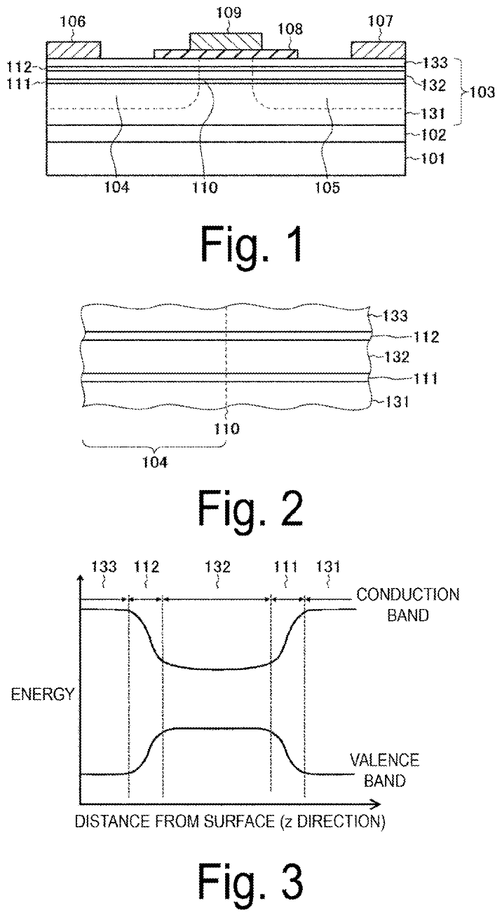

Hereinafter, a tunnel field effect transistor according to an embodiment of the present invention will be described with reference to FIGS. 1 and 2. This tunnel field effect transistor includes an InP layer 102 that comprises InP and is formed on a substrate 101, and a channel layer 103 formed on the InP layer 102. The tunnel field effect transistor further includes a p-type source region 104 formed in the channel layer 103 and an n-type drain region 105 formed in the channel layer 103 at a predetermined interval from the source region 104.

The tunnel field effect transistor also includes a source electrode 106 formed in electrical connection with the source region 104, a drain electrode 107 formed in electrical connection with the drain region 105, and a gate electrode 109 formed on the undoped region (channel region) between the source region 104 and the drain region 105. The gate electrode 109 is formed above the channel region via a gate insulating layer 108. The gate electrode may also be configured to be Schottky connected.

The channel layer 103 has a quantum well structure comprising InGaAs or InGaAsSb. The quantum well structure includes, for example, a barrier layer 131, a well layer 132, and a barrier layer 133 laminated from the side of the substrate 101.

The tunnel field effect transistor according to the embodiment further includes an intermediate layer 111 formed between the barrier layer 131 and the well layer 132 and an intermediate layer 112 formed between the barrier layer 133 and the well layer 132. The intermediate layers in and 112 comprise InGaAs or InGaAsSb having an In composition ratio greater than that of the barrier layers 131 and 133 and smaller than that of the well layer 132.

For example, the In composition ratio of the intermediate layers 111 and 112 may be set higher toward the well layer 132. Further, the intermediate layers 111 and 112 may be composition gradient layers in which the In composition ratio continuously decreases from the well layer 132 to the barrier layers 131 and 133 so that there is no band discontinuity.

In this tunnel field effect transistor, the interface between the source region 104 and the undoped region (channel region) is a tunnel junction region 110. This tunnel field effect transistor realizes on/off operation by changing the current flowing to the drain region 105 by controlling the electric field applied to the tunnel junction region 110 by the gate voltage.

In the planar tunnel field effect transistor including the quantum well structure in the embodiment, the intermediate layers 111 and 112 are provided to reduce the influence of band curvature at the heterojunction interfaces between the well layer 132 and the barrier layers 131 and 133, thereby suppressing the increase in the off-current due to the heterojunction interface.

Hereinafter, in the tunnel field effect transistor described with reference to FIGS. 1 and 2, the band state in the source region 104 will be described with reference to FIG. 3. Hereinafter, the band arrangement in the thickness direction in the source region 104 of the channel layer 103, in which the intermediate layers 111 and 112 are composition gradient layers, will be described.

Since there is no band discontinuity at the interfaces between the well layer 132 and the barrier layers 131 and 133 in the undoped state, basically no spike occur in the valence band of the well layer 132 even in the p-type doped source region 104. Therefore, in the tunnel field effect transistor using this quantum well structure as the channel layer 103, the increase in leakage current due to crystal defects at the interfaces between the well layer 132 and the barrier layers 131 and 133 is suppressed in the source region 104. Further, in the quantum well structure in which the intermediate layers iii and 112 are inserted, since there is no spike in the well layer 132, electron tunneling can be used not only near the interfaces but also in the entire well layer 132, this is also effective in increasing the tunnel current.

In order not to form spikes in the valence band of the well layer 132, the composition (In composition) preferably continuously changes between the well layer 132 and the barrier layers 131 and 133 as described above. However, depending on the crystal growth method and the composition of the well layer 132 and the barrier layers 131 and 133, the continuous change of the composition may be difficult. In this case, the spikes can be reduced by using the method described below.

The spikes in the valence band of the well layer 132 basically become larger as the difference in composition between the well layer 132 and the barrier layers 131 and 133 increases. Therefore, in order to reduce the spikes, a layer having a composition similar to that of the well layer 132 is brought to close to the well layer 132. Further, when the compositions of the well layer 132 and the barrier layers 131 and 133 are significantly different, layers having intermediate compositions are inserted between the well layer 132 and the barrier layers 131 and 133 in several steps. The number of intermediate layers to be inserted is determined at the design stage in consideration of the difference in composition between the well layer 132 and the barrier layers 131 and 133, the film thickness of the intermediate layer, and the ease of crystal growth.

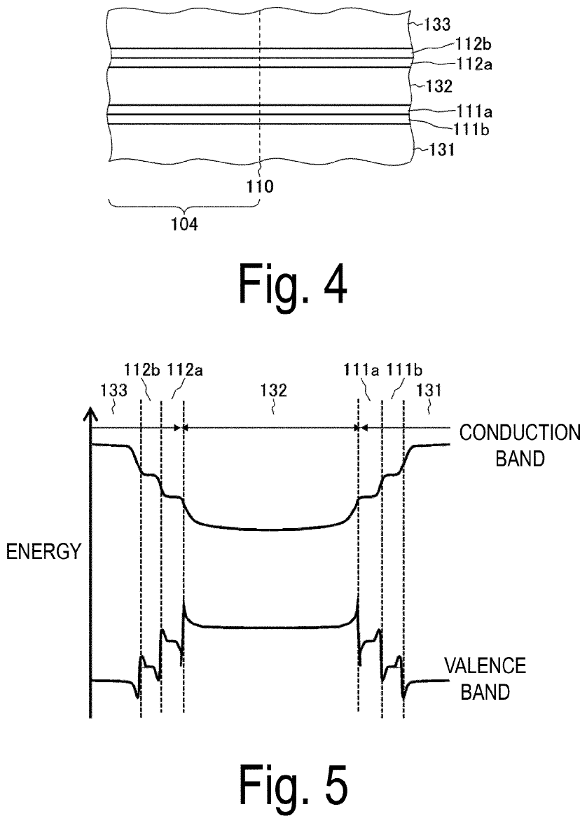

For example, as illustrated in FIG. 4, a first intermediate layer 111a and a second intermediate layer 111b are provided between the barrier layer 131 and the well layer 132, and a first intermediate layer 112a and a second intermediate layer 112b are provided between the well layer 132 and the barrier layer 133. The first intermediate layers 111a and 112a have a higher In composition ratio than the second intermediate layers 111b and 112b. In this configuration, the In composition is changed stepwise between the well layer 132 and the barrier layers 131 and 133.

The band state of the tunnel field effect transistor described with reference to FIG. 4 in the source region 104 will be described below with reference to FIG. 5. The band arrangement in the thickness direction in the source region 104 of the channel layer 103 when the first intermediate layers 111a and 112a and the second intermediate layers 111b and 112b are used will be described below.

By reducing the difference in the bandgap between the well layer 132 and the first intermediate layers 111a and 112a in contact with the well layer 132, the spikes in the valence band of the well layer 132 can be reduced. As a result, the off-current can be reduced and the ratio of the on-current to the off-current can be increased, as in the case of the above-described quantum well structure including the composition gradient layer.

Next, the method for manufacturing the tunnel field effect transistor described with reference to FIGS. 1 and 2 will be described. First, the production of a laminated structure including the InP layer 102, the barrier layer 131, the intermediate layer 111, the well layer 132, the intermediate layer 112, and the barrier layer 133 will be described. The production of the laminated structure uses metalorganic molecular beam epitaxy (MOMBE) using trimethylindium (TMIn) and triethylgallium (TEGa) as the group III raw material gas, and phosphine (PH₃), arsine (AsH₃), and trisdimethylaminoantimony (TDMASb) as the group V raw material gas.

First, on the substrate 101 comprising semi-insulating InP, the InP layer 102 having a layer thickness of 30 nm, the barrier layer 131 having a layer thickness of 90 nm and comprising InGaAs, the intermediate layer 111 having a layer thickness of 1.5 nm in which the composition of InGaAs was continuously changed, the well layer 132 having a layer thickness of 7 nm and comprising InGaAs, the intermediate layer 112 having a layer thickness of 1.5 nm in which the composition of InGaAs was continuously changed, and the barrier layer 133 having a layer thickness of 3 nm and comprising InGaAs were grown in this order to prepare a laminated structure. The In composition ratio of the barrier layer 131 and the barrier layer 133 is 0.53, and the In composition ratio of InGaAs in the well layer 132 is 0.78.

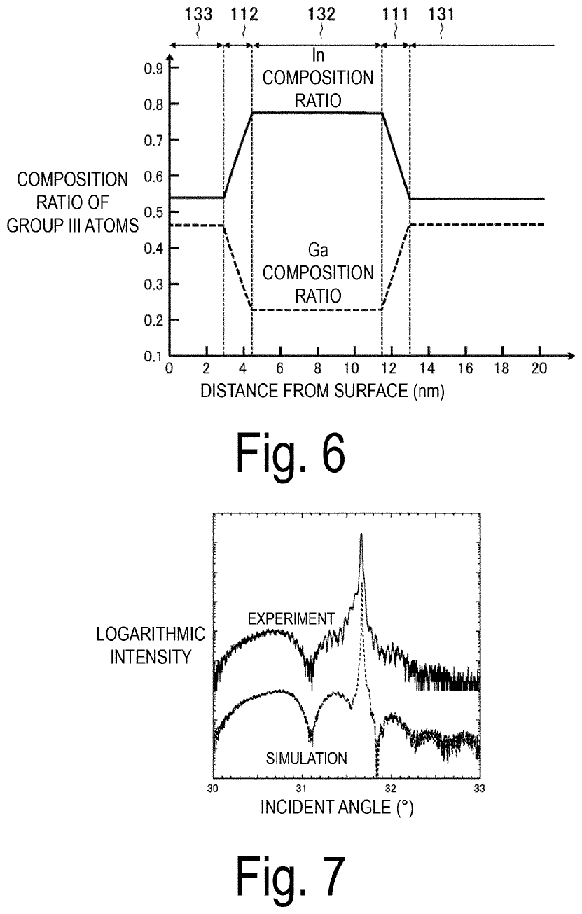

FIG. 6 illustrates changes in the In composition ratio and the Ga composition ratio of InGaAs from the surface side in the above-described laminated structure. As the distance from the crystal surface increases, the In composition ratio of the intermediate layer 112 is continuously increased from 0.53 to 0.78, and the In composition ratio of the intermediate layer 111 is continuously decreased from 0.78 to 0.53. For comparison, a laminated structure (comparative laminated structure) without the intermediate layers iii and 112 was also produced, in which the thickness of the barrier layers was increased so as to correspond to the intermediate layers.

After ion implantation of silicon into the region to be the drain region 105 for each of the above-described laminated structure and comparative laminated structure, necessary heat treatment is performed to activate the silicon to form the n-type drain region 105. After that, Al₂O₃ is deposited by atomic layer deposition (ALD) over the entire substrate to form an insulating film, and then the Al₂O₃ in the region to be a source region 104 is removed to form an opening in the insulating film to form a mask pattern. After cleaning the surface of the substrate on which the mask pattern is formed, the temperature of the substrate 101 is raised in an organometallic vapor phase epitaxy (MOVPE) apparatus while supplying phosphine and diethylzinc (DEZn). As a result, in the opening of the mask pattern, Zn is doped (diffused) from the surface of the exposed barrier layer 133 to the middle of the barrier layer 131 to obtain the source region 104.

After that, for element separation, the laminated structure other than the region where the element is produced is removed, and then the insulating material is deposited in the region to be a gate by using the atomic layer deposition method to form the gate insulating layer 108. Next, the metal to be the gate electrode 109 is vapor-deposited by an electron beam vapor deposition apparatus, and the deposited metal is removed from the region other than the region to be the gate electrode 109 using the lift-off process. The gate electrode 109 is formed to have a gate length of about 1 μm.

Next, the insulating material (gate insulating layer 108) in the region where the source electrode and the drain electrode are formed is removed, and the source electrode 106 and the drain electrode 107 are formed using the lift-off process. Finally, heat treatment necessary for electrode formation such as obtaining an ohmic connection of the source electrode 106 and the drain electrode 107 was performed, thus producing a sample of the tunnel field effect transistor according to the embodiment and a comparative sample.

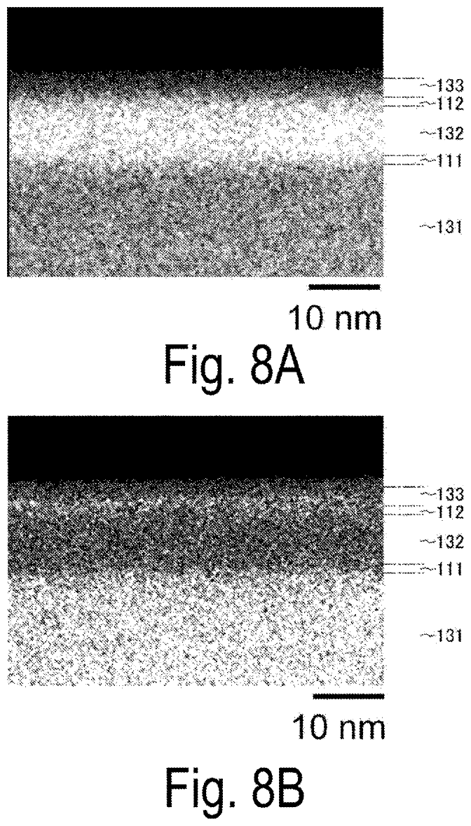

Here, the crystal evaluation result of the produced laminated structure will be described. FIG. 7 is a characteristic diagram comparing an experimental X-ray diffraction pattern (solid line) and a simulated X-ray diffraction pattern (dotted line) of the above-described laminated structure including the InP layer 102, the barrier layer 131, the intermediate layer 111, the well layer 132, the intermediate layer 112, and the barrier layer 133. The simulation is calculated assuming the above-described laminated structure. The experimental results were in good agreement with the simulation results, and it was found that the thickness and composition of the well layer 132 and the barrier layers 131 and 133 were almost as designed.

On the other hand, since the intermediate layers 111 and 112 have a thin layer thickness of 1.5 nm, their evaluation by X-ray diffraction is difficult. Therefore, crystal evaluation of the laminated structure was carried out using energy dispersive X-ray spectroscopy (EDS) with high spatial resolution.

FIGS. 8A and 8B are the results of examining the distribution state of In and Ga near the crystal surface of the above-described laminated structure using EDS. For both the results of In and Ga, the brighter the color, the higher the composition ratio, and the darker the color, the lower the composition ratio. In FIGS. 8A and 8B, since there is no region where the light and darkness changes rapidly, it can be seen that the In and Ga compositions change continuously between the well layer 132 and the barrier layers 131 and 133. EDS can determine the approximate proportion by analyzing the intensity of characteristic X-rays from each atom in its spectrum (precise quantitative analysis of InGaAs is difficult due to the effects of impurities during the preparation of observation samples).

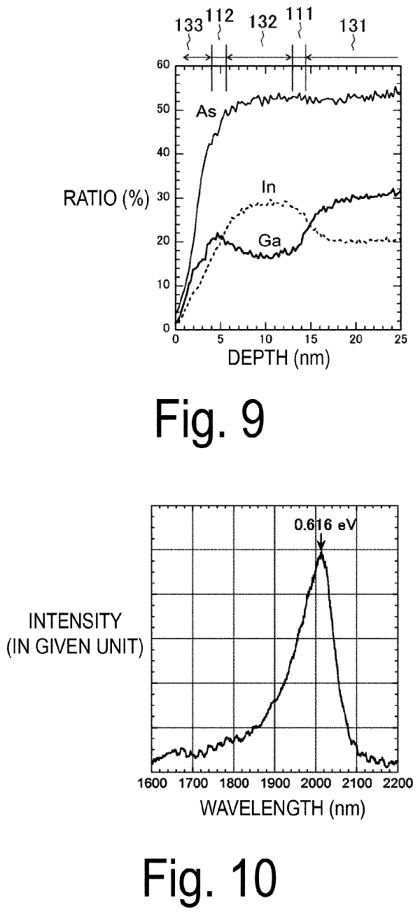

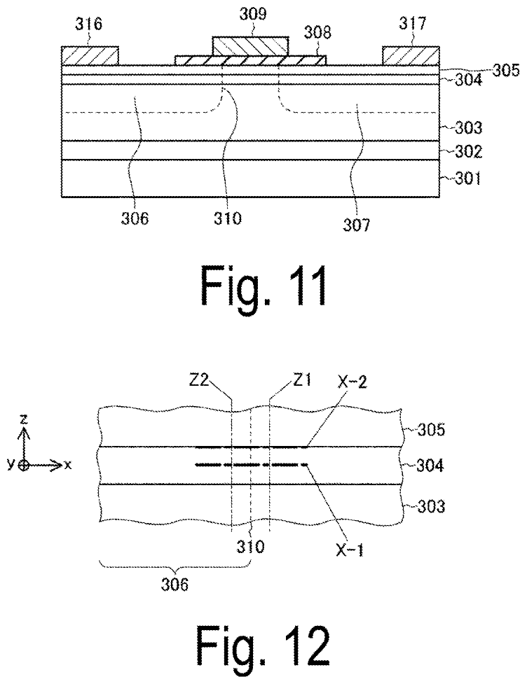

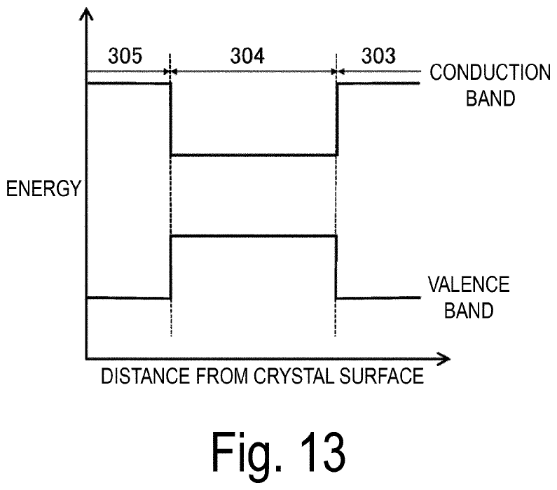

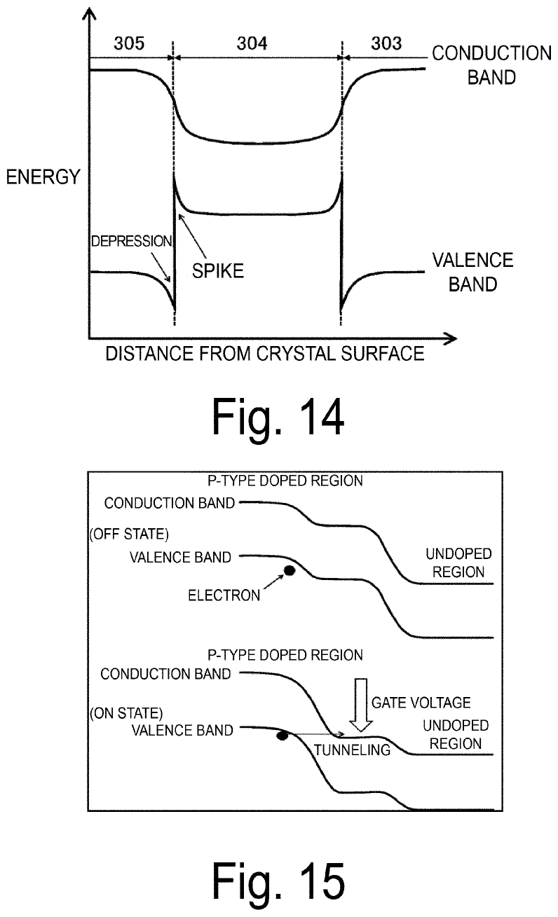

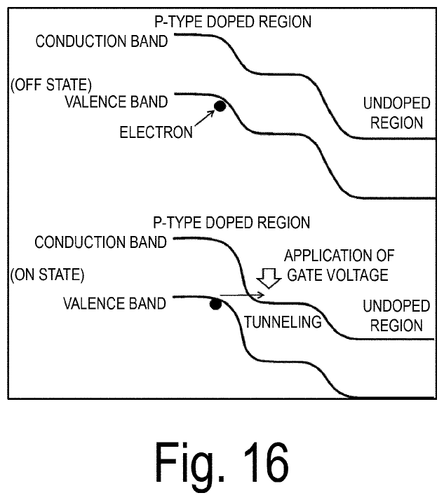

FIG. 9 illustrates the ratios of In, Ga, and As of the laminated structure obtained by analyzing the spectrum of this EDS. In FIG. 9, between the barrier layers 131 and 133 and the well layer 132, the ratio of Ga and the ratio of In continuously change in the depth direction, indicating that the intermediate layers 111 and 112 having composition gradients as designed are inserted.

FIG. 10 illustrates the photoluminescence spectrum of the above-described laminated structure at room temperature. The energy of the emission peak of photoluminescence is 0.616 eV. In the channel layer 103 of the quantum well structure, the energy of the emission peak and the bandgap of the well layer 132 substantially match. Therefore, it was found that the bandgap in the channel layer 103 of the quantum well structure used for this tunnel field effect transistor is smaller than that of InGaAs (0.74 eV) lattice-matched to InP.

Next, the evaluation of the sample of the produced tunnel field effect transistor and the comparative sample will be described. In the sample provided with the intermediate layer, the drain current when the source voltage is 60 mV is 8×10⁻⁷ μA/μm (off-current) when the gate voltage is 0 V, and 8×10⁻¹ μA/μm (on-current) when the gate voltage is 0.6 V. Therefore, the ratio of the on-current to the off-current is 1×10⁶.

In the comparative sample prepared from the comparative laminated structure without the intermediate layer, the drain current when the source voltage is 60 mV is 1×10⁻⁶ μA/μm (off-current) when the gate voltage is 0 V, and 7×10⁻¹ μA/μm (on-current) when the gate voltage is 0.6 V. Therefore, the ratio of the on-current to the off-current is 7×10⁵.

As is clear from the comparison between the sample described above and the comparative sample, the insertion of the intermediate layers lowers the off-current and increases the on-current, resulting in an increase in the ratio of the on-current to the off-current.

From the above, it can be seen that both of the on-current and the ratio of the on-current and the off-current can be increased by providing intermediate layers between the barrier layers and the well layer of the channel layer having a quantum well structure.

The above description illustrates an example in which the well layer, the barrier layers, and the intermediate layers comprise InGaAs. Even if InGaAs is replaced with InGaAsSb, the production process of the above-described laminated structure and the tunnel field effect transistor does not change significantly. Therefore, it is clear that the device characteristics are improved in the same manner as described above, even when InGaAsSb is used for any of the well layer, the barrier layer, and the intermediate layer.

Further, inserting several intermediate layers, which have a uniform intermediate composition in the thickness direction, between the well layer and the barrier layers is easier than inserting an intermediate layer having a composition gradient with continuously changed composition. For this reason, it is clear that the device characteristics are improved as described above even in a tunnel field effect transistor that includes a quantum well structure as a channel layer, in which several intermediate layers, each with a uniform intermediate composition in the thickness direction, are inserted between the well layer and the barrier layers.

In the above, an example in which metalorganic molecular beam epitaxy (MOMBE) is used as the crystal growth method of the laminated structure has been described. However, the method is not limited to MOMBE, and may be any method as long as it can produce a quantum well structure by crystal growth, such as molecular beam epitaxy (MBE), metalorganic vapor phase epitaxy (MOVPE), or gas-source molecular beam epitaxy (GSMBE).

As described above, according to embodiments of the present invention, since intermediate layers comprising InGaAs or InGaAsSb and having an In composition ratio greater than that of the barrier layers and smaller than that of the well layer are formed between the well layer and the barrier layers constituting the channel layer, the off-current of the tunnel field effect transistor having the quantum well structure channel layer as the quantum well structure can be reduced.

According to embodiments of the present invention, in a tunnel field effect transistor using a quantum well structure, the ratio of the on-current to the off-current can be increased, and the device characteristics can be improved. As a result, there is an effect that the power consumption of the IT equipment can be reduced by using the tunnel field effect transistor for the electronic component.

Meanwhile, the present invention is not limited to the embodiments described above, and it will be obvious to those skilled in the art that various modifications and combinations can be implemented within the technical idea of the present invention.

### Reference Signs List

101 Substrate, 102 InP layer, 103 Channel layer, 104 Source region, 105 Drain region, 106 Source electrode, 107 Drain electrode, 108 Gate insulating layer, 109 Gate electrode, 110 Tunnel junction region, 111, 112 Intermediate layer, 131, 133 Barrier layer, 132 Well layer

1-4. (canceled)

5. A tunnel field effect transistor comprising:
an intermediate layer between a well layer and a barrier layer, the intermediate layer comprising InGaAs or InGaAsSb and having an In composition ratio greater than an In composition ratio of the barrier layer and smaller than an In composition ratio of the well layer, the well layer and the barrier layer defining a channel layer having a quantum well structure;
a source region in the channel layer, the source region being of p-type;
a drain region in the channel layer at a predetermined interval from the source region, the drain region being of n-type;
a source electrode electrically connected to the source region;
a drain electrode electrically connected to the drain region; and
a gate electrode above a channel region between the source region and the drain region.

6. The tunnel field effect transistor according to claim 5, wherein the In composition ratio of the intermediate layer is higher toward the well layer.

7. The tunnel field effect transistor according to claim 6, wherein the In composition ratio of the intermediate layer continuously decreases from the well layer to the barrier layer.

8. A method for manufacturing a tunnel field effect transistor, the method comprising:
forming a laminated structure on a substrate, wherein forming the laminated structure comprises:
forming an InP layer on the substrate;
forming a first barrier layer on the InP layer;
forming a first intermediate layer comprising InGaAs or InGaAsSb on the first barrier layer;
forming a well layer on the first intermediate layer, the well layer and the first barrier layer defining a channel layer having a quantum well structure, wherein the first intermediate layer has an In composition ratio greater than an In composition ratio of the first barrier layer and smaller than an In composition ratio of the well layer;
forming a source region in the channel layer, the source region being of p-type, wherein the source region is made p-type by Zn diffusion;
forming a drain region in the channel layer at a predetermined interval from the source region, the drain region being of n-type;
forming a gate electrode above a channel region between the source region and the drain region;
forming a source electrode electrically connected to the source region; and
forming a drain electrode electrically connected to the drain region.

9. The method according to claim 8, wherein forming the laminated structure further comprises:
forming a second intermediate layer comprising InGaAs or InGaAsSb on the well layer; and
forming a second barrier layer on the second intermediate layer.

10. The method according to claim 9, wherein the first intermediate layer and the second intermediate layer comprise InGaAs, and wherein a composition of the InGaAs in the first intermediate layer and in the second intermediate layer is continuously changed.

11. The method according to claim 8, wherein the first intermediate layer comprises a plurality of first intermediate layers comprising InGaAs, each of the plurality of first intermediate layers having a uniform intermediate composition in a thickness direction that is different from the uniform intermediate composition of an adjacent one of the plurality of first intermediate layers such that the In composition ratio of the plurality of first intermediate layers continuously decreases from an initial intermediate layer of the plurality of first intermediate layers closest to the well layer to a final intermediate layer of the plurality of first intermediate layers closest to the first barrier layer.

12. The method according to claim 8, wherein forming the laminated structure comprises a metalorganic molecular beam epitaxy process, a molecular beam epitaxy process, a metalorganic vapor phase epitaxy process, or a gas-source molecular beam epitaxy process.

13. The method according to claim 8, further comprising depositing a gate insulating layer above the channel region, wherein the gate electrode is formed on the gate insulating layer.

14. The method according to claim 8, wherein the In composition ratio of the first intermediate layer is higher toward the well layer.

15. The method according to claim 8, wherein the In composition ratio of the first intermediate layer continuously decreases from the well layer to the first barrier layer.
